(19) United States
(12) Patent Application Publication
(10) Pub. No.: US 2010/0226089 A1
(43) Pub. Date: Sep. 9, 2010

(54) HINGE ASSEMBLY AND ELECTRONIC DEVICE USING THE SAME

(75) Inventors: JIN-XIN WANG, Shenzhen City (CN); CHAO-ZHONG FU, Shenzhen City (CN); JIAN LI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/503,800

(22) Filed: Jul. 15, 2009

(30) Foreign Application Priority Data
Mar. 7, 2009 (CN) 200910300736.X

(51) Int. Cl. H05K 5/00; E05F 1/08; E05D 11/06

(52) U.S. Cl. 361/679.55; 16/297; 361/679.01

(57) ABSTRACT

A hinge assembly includes a pivot shaft, a rotatable stand, a fixed stand, a torsion spring, and a restricting member. The rotatable stand is non-rotatably connected to the pivot shaft. The torsion spring is connected to the rotatable stand and the fixed stand, to generate a torsion force to rotate the rotatable stand. The restricting member is sleeved on the pivot shaft. The fixed stand has a positioning portion. The positioning portion defines a plurality of sliding grooves. The restricting member forms a plurality of sliding protrusions received in the sliding grooves. A first sloping surface is formed at an end of each sliding groove. The sliding protrusions are smaller than the sliding grooves. When the rotatable stand rotates relative to the fixed stand, the sliding protrusions accelerate in the sliding grooves, and decelerate on the first sloping surface.

### CROSS-REFERENCE TO RELATED APPLICATIONS

This application is related to four co-pending U.S. patent applications, application Ser. No. 12/261,225 filed on Oct. 30, 2008, entitled “HINGE ASSEMBLY”, application Ser. No. 12/261,230 filed on Oct. 30, 2008, entitled “HINGE ASSEMBLY”, application Ser. No. 12/396,557 filed on Mar. 3, 2009, entitled “HINGE ASSEMBLY”, application Ser. No. 12/417,817 filed on Apr. 3, 2008, entitled “HINGE ASSEMBLY”. The co-pending applications have the same assignee as the present application.

### BACKGROUND

1. Technical Field

The present disclosure relates generally to hinge assemblies and electronic devices using the same and, more particularly, to a hinge assembly for a foldable electronic device.

2. Description of Related Art

A typical foldable electronic device such as a notebook computer generally has a main body and a cover with a display hinged on the main body via a typical hinge.

The typical hinge includes a pivot shaft, a first stand, a second stand, a restricting assembly, and a torsion spring. The pivot shaft includes a shaft portion and a connecting portion formed on an end of the shaft portion. The first stand, the restricting assembly, and the torsion spring are sleeved on the shaft portion. The second stand is non-rotatably sleeved on the connecting portion. The restricting assembly includes a cam and a cam follower. The cam is rotatably connected to the shaft portion, and the cam follower is non-rotatably connected to the shaft portion. A plurality of protrusions is formed on a side surface of the cam. The cam follower defines a plurality of notches receiving the protrusions. The torsion spring has two connecting pegs. One connecting peg is connected to the first stand, and the other connecting peg is connected to the second stand. In use, the first stand is connected to the main body, and the second stand is connected to the cover. After the cover is rotated away from the main body by a predetermined angle, the protrusions of the cam disengage from the notches of the cam follower, and the cover is driven to rotate by a force of the torsion spring.

However, increases in the rotating speed of the cover can generate a large impact force because of the force of the torsion spring. When the protrusions of the cam engage the notches of the cam follower again, the cover stops suddenly, experiencing a considerable impact force. The cam and the cam follower are easily damaged, as well as electronic components inside the cover.

Therefore, a hinge assembly and an electronic device using the same solving the limitations described are desirable.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an embodiment of an electronic device including a main body, a cover, and a hinge assembly.

FIG. 2 is an exploded, isometric view of an embodiment of a hinge assembly for use in an electronic device, the hinge assembly including a fixed stand, a rotatable stand, a restricting member, and a torsion spring.

FIG. 3 is similar to FIG. 2, but viewed from another aspect.

FIG. 4 is a partial, isometric view of the fixed stand and the restricting member of FIG. 3.

FIG. 5 is an assembled, isometric view of the hinge assembly in FIG. 2.

### DETAILED DESCRIPTION

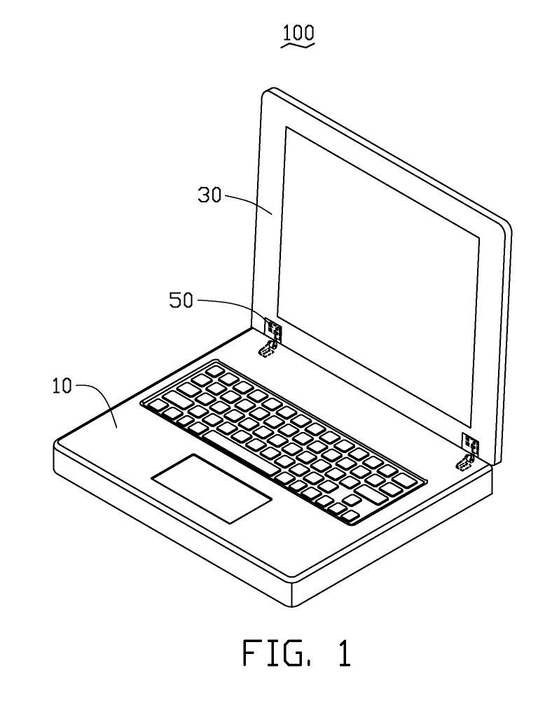

Referring to FIG. 1, an embodiment of an electronic device 100 includes a main body 10, a cover 30, and two hinge assemblies 50 connecting the cover 30 with the main body 10. In the illustrated embodiment, the electronic device 100 is a notebook computer.

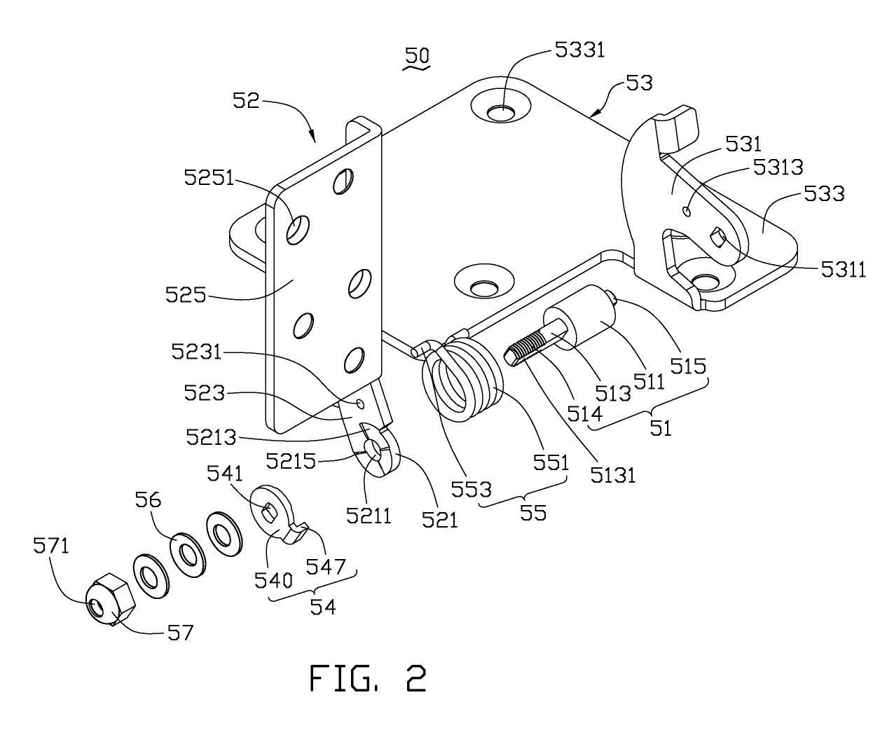

Referring to FIG. 2, an embodiment of a hinge assembly 50 includes a pivot shaft 51, a fixed stand 52, a rotatable stand 53, a restricting member 54, a torsion spring 55, a plurality of spring washers 56, and a fastening member 57.

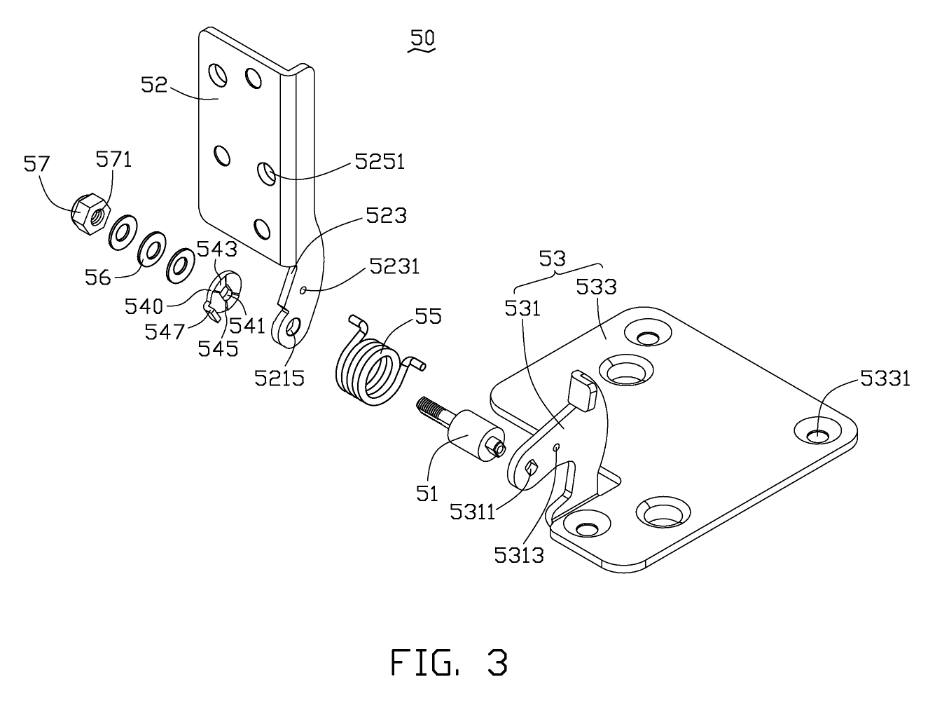

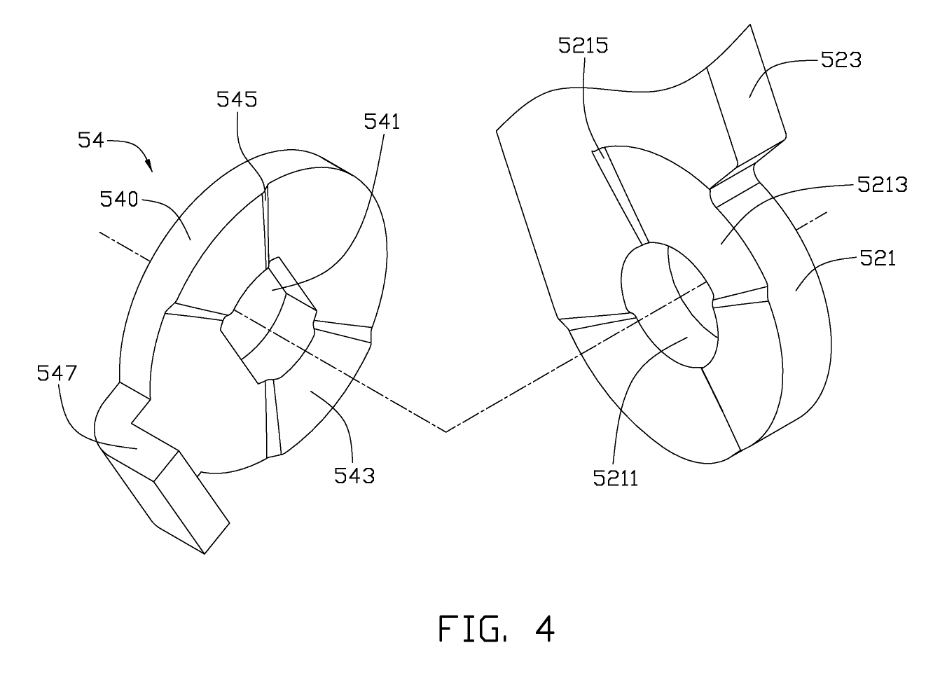

Referring to FIGS. 2 through 4, the pivot shaft 51 includes a shaft portion 513, a resisting portion 511 formed on a proximal end of the shaft portion 513, a threaded portion 514 formed on a distal end of the shaft portion 513, and a shaft head 515 formed on an end of the resisting portion 511 along an extending axis of the shaft portion 513. The shaft portion 513 has two positioning surfaces 5131 on opposite sides of the shaft portion 513. The shaft head 515 defines two positioning surfaces (not shown) on opposite sides of the shaft head 515.

The fixed stand 52 includes a positioning portion 521, a base plate 523, and a fixing plate 525. The positioning portion 521 extends from an end of the base plate 523. The fixing plate 525 extends substantially perpendicularly from a side of the base plate 523. The positioning portion 521 is substantially a circular plate. A center of the positioning portion 521 defines a circular pivot hole 5211. The positioning portion 521 further defines two sliding grooves 5213 on opposite ends. Each end of the sliding groove 5213 forms a first sloping surface 5215. The base plate 523 defines a first fixing hole 5231 adjacent to the positioning portion 521. The fixing plate 525 defines a plurality of assembling holes 5251 for connecting the hinge assembly 50 to the main body 10 of the electronic device 100.

The rotatable stand 53 includes a fixing plate 533 and a connecting plate 531 extending substantially perpendicularly from a side of the fixing plate 533. The connecting plate 531 defines a connecting hole 5311 corresponding to the shaft head 515, and a second fixing hole 5313 adjacent to the connecting hole 5311. The fixing plate 533 defines a plurality of assembling holes 5331 for connecting the hinge assembly 50 to the cover 30 of the electronic device 100.

The restricting member 54 includes a main portion 540 and a restricting piece 547 extending from an edge of the main portion 540. The main portion 540 defines a through hole 541 in a center thereof. Two sliding protrusions 543 are formed on a side surface of the main portion 540. Two second sloping surfaces 545 are formed on opposite ends of each sliding protrusion 543. The sliding protrusions 543 are smaller than the sliding grooves 5213, and are thus slidably accommodating therein for a predetermined distance.

The torsion spring 55 includes a main body 551 and two pegs 553 extending from opposite ends of the main body 551.

The hinge assembly may further include a plurality of spring washers 56. In the illustrated embodiment, the hinge assembly 50 includes three spring washers 56. The fastening member 57 engages with the threaded portion 514 of the pivot shaft 51. In the illustrated embodiment, the fastening member 57 is a nut.

In assembling the hinge assembly 50, the torsion spring 55 sleeves on the resisting portion 511. The fixed stand 52, the restricting member 54, and the spring washers 56 sleeve on the shaft portion 513 of the pivot shaft 51. The shaft head 515 engages in the connecting hole 5311 of the rotatable stand 53. One peg 553 of the torsion spring 55 engages in the first fixing hole 5231 of the base plate 523, and the other peg 553 of the torsion spring 55 engages in the second fixing hole 5313 of the rotatable stand 53. The fastening member 57 engages with the threaded portion 514 of the pivot shaft 51.

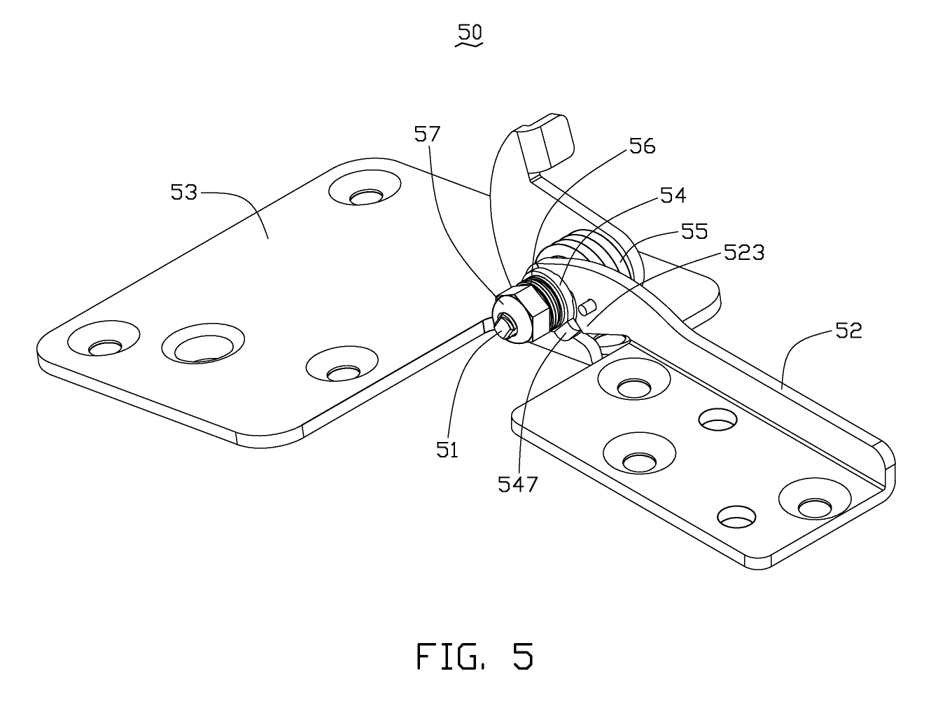

Referring to FIGS. 1, 2, and 5, in use, the fixed stand 52 is connected to the main body 10, and the rotatable stand 53 is connected to the cover 30, thus rotatably connecting the cover 30 to the main body 10. The cover 30 can be locked on the main body 10 via a locking mechanism (not shown), such as an engaging hook defined on the cover 30 and a positioning groove receiving the engaging hook defined in the main body 10. In this situation, the torsion spring 55 deforms to generate torsion force, and the sliding protrusions 543 of the restricting member 54 are received in the sliding grooves 5213 of the fixed stand 52. When the cover 30 is unlocked from the main body 10, the rotatable stand 53 rotates away from the fixed stand 52 driven by a force of the torsion spring 55. Thus, the cover 30 connected to the rotatable stand 53, rotates away from the main body 10.

In a rotating process of the rotatable stand 53, the sliding protrusion 543 of the restricting member 54 accelerates in the sliding grooves 5213 of the fixed stand 52 driven by the force of the torsion spring 55. When the second sloping surfaces 545 of the restricting member 54 resist the first sloping surfaces 5215, the spring washers 56 are compressed, and a friction force between the sliding protrusions 543 and the fixed stand 52 exceeds the force of the torsion spring 55. Therefore, the speed of the sliding protrusions 543 gradually decreases. The restricting member 54 stops rotating when the restricting piece 547 resists the base plate 523 of the fixed stand 52.

As described, the cover 30 can be opened automatically by the force of the torsion spring 55. Further, the rotatable stand 53 can accelerate relative to the fixed stand 52 until the second sloping surfaces 545 of the restricting member 54 resist the first sloping surfaces 5215, and decelerate due to the friction force between the second sloping surfaces 545 and the first sloping surfaces 5215. That is, an opening speed of the cover 30, which is connected to the rotatable stand 53, can be adjusted, thus preventing the hinge assembly 50 from suffering an impact force caused by the cover 30. Therefore, the hinge assembly 50 has a long service life.

It should be pointed out that the sliding protrusions may be formed on the fixed stand 52, and the sliding grooves 5213 formed in the restricting member 54. The fixed stand 52 may also define one sliding groove 5213 or more than two sliding grooves 5213, and accordingly, the restricting member 54 would define one sliding protrusion 543 or more than two sliding protrusions 543. In addition, the fixed stand 52 may not define sliding grooves 5213, but only form the first sloping surface 5215. In this situation, the cover can also accelerate at the beginning of, and decelerate at the end of a rotation.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A hinge assembly, comprising:
a pivot shaft;
a rotatable stand;
a fixed stand comprising a positioning portion;
a torsion spring sleeved on the pivot shaft and connected to the rotatable stand and the fixed stand, to generate a torsion force to rotate the rotatable stand relative to the fixed stand; and
a restricting member sleeved on the pivot shaft;
wherein one of the rotatable stand and fixed stand is non-rotatably connected to the pivot shaft; one of the positioning portion and the restricting member defines at least one sliding groove, and the other one of the positioning portion and the restricting member forms at least one sliding protrusion received in the at least one sliding groove; a first sloping surface is formed at an end of the at least one sliding groove; the at least one sliding protrusion is smaller than the at least one sliding groove; and when the rotatable stand rotates relative to the fixed stand, the at least one sliding protrusion accelerates in the at least one sliding groove, and decelerates on the first sloping surface.

2. The hinge assembly of claim 1, wherein the pivot shaft comprises a shaft portion, a resisting portion is formed on a first end of the shaft portion, and a threaded portion is formed on a second end of the shaft portion.

3. The hinge assembly of claim 2, wherein the torsion spring comprises a main body and two pegs extending from opposite ends of the main body; the main body is sleeved on the resisting portion; one peg is connected to the fixed stand, and the other peg is connected to the rotatable stand.

4. The hinge assembly of claim 2, further comprising a fastening member engaging with the threaded portion.

5. The hinge assembly of claim 1, wherein the fixed stand further comprises a base plate connected to the positioning portion; the restricting member comprises a restricting piece; and the restricting piece and the base plate cooperatively define a rotating angle range of the rotatable stand.

6. The hinge assembly of claim 1, wherein the at least one sliding protrusion defines a second sloping surface corresponding to the first sloping surface.

7. The hinge assembly of claim 1, further comprising a plurality of spring washers sleeved on the pivot shaft.

8. A hinge assembly, comprising:
a pivot shaft;
a rotatable stand;
a fixed stand comprising a positioning portion, the positioning portion forming a first sloping surface;
a torsion spring sleeved on the pivot shaft and connected to the rotatable stand and the fixed stand, to generate a torsion force to rotate the rotatable stand relative to the fixed stand; and
a restricting member sleeved on the pivot shaft, the restricting member forming at least one sliding protrusion;
wherein one of the rotatable stand and the fixed stand is non-rotatably connected to the pivot shaft; and when the rotatable stand rotates relative to the fixed stand, the at least one sliding protrusion accelerates towards the first sloping surface driven by force of the torsion spring, and decelerates on the first sloping surface.

9. The hinge assembly of claim 8, wherein the pivot shaft comprises a shaft portion, a resisting portion is formed on a first end of the shaft portion, and a threaded portion is formed on a second end of the shaft portion.

10. The hinge assembly of claim 9, wherein the torsion spring comprises a main body and two pegs extending from opposite ends of the main body; the main body is sleeved on the resisting portion; one peg is connected to the fixed stand, and the other peg is connected to the rotatable stand.

11. The hinge assembly of claim 9, further comprising a fastening member engaging with the threaded portion.

12. The hinge assembly of claim 8, wherein the fixed stand further comprises a base plate connected to the positioning portion; the restricting member comprises a restricting piece; and the restricting piece and the base plate cooperatively define a rotating angle range of the rotatable stand.

13. The hinge assembly of claim 8, wherein the at least one sliding protrusion defines a second sloping surface corresponding to the first sloping surface.

14. The hinge assembly of claim 8, further comprising a plurality of spring washers sleeved on the pivot shaft.

15. An electronic device, comprising:
a main body;
a cover; and
a hinge assembly rotatably connecting the cover to the main body, comprising:
a pivot shaft;
a rotatable stand;
a fixed stand comprising a positioning portion and a base plate connecting the positioning portion;
a torsion spring sleeved on the pivot shaft and connected to the rotatable stand and the fixed stand respectively, to generate a torsion force to rotate the rotatable stand relative to the fixed stand; and
a restricting member sleeved on the pivot shaft and comprising a restricting piece;
wherein one of the rotatable stand and the fixed stand is non-rotatably connected to the pivot shaft, the restricting piece and the base plate cooperatively define a rotating angle range of the rotatable stand; one of the positioning portion and the restricting member forms at least one sliding protrusion, the other one of the positioning portion and the restricting member has a first sloping surface; and when the rotatable stand rotates relative to the fixed stand, the at least one sliding protrusion contacts the sloping surface before the restricting piece contacts the base plate.

16. The electronic device of claim 15, wherein the pivot shaft comprises a shaft portion, a resisting portion is formed on a first end of the shaft portion, and a threaded portion is formed on a second end of the shaft portion.

17. The electronic device of claim 16, wherein the torsion spring comprises a main body and two pegs extending from opposite ends of the main body; the main body is sleeved on the resisting portion; one peg is connected to the fixed stand, and the other peg is connected to the rotatable stand.

18. The electronic device of claim 16, wherein the hinge assembly further comprises a fastening member engaging with the threaded portion.

19. The electronic device of claim 15, wherein the at least one sliding protrusion defines a second sloping surface corresponding to the first sloping surface.

20. The electronic device of claim 15, wherein the electronic device is a notebook computer.
